(19) United States
(12) Patent Application Publication
(10) Pub. No.: US 2002/0125495 A1
(43) Pub. Date: Sep. 12, 2002

(54) Thin film alternating current electroluminescent displays

(75) Inventors: Andrew J. Steckl, Cincinnati, OH (US); Jason C. Heikenfeld, Cincinnati, OH (US)

Correspondence Address: Wood, Herron & Evans, L.L.P., 2700 Carew Tower, 441 Vine Street, Cincinnati, OH, 45202-2917, US

(73) Assignee: University of Cincinnati

(21) Appl. No.: 09/804,206

(22) Filed: Mar. 12, 2001

(51) Int. Cl. H01L 33/00

(52) U.S. Cl. 257/103

(57) ABSTRACT

Wide band gap semiconductor materials doped with rare earths or other light emitting metal form alternating current electroluminescent devices. The semiconductors are preferably gallium nitride, indium nitride or aluminum nitride and the electric luminescent device may have an upper and lower thin coat of a dielectric material in turn connected to alternating current electrodes.

### BACKGROUND OF THE INVENTION

The next generation of flat panel displays is seeking to provide advances in brightness, efficiency, color, purity, resolution, scalability, reliability and reduced costs. One such technology is thin film electroluminescence (TFEL) inorganic phosphors. TFEL displays can provide high brightness, outstanding durability and reliability. Current inorganic TFEL phosphors are composed of group II-VI wide band gap semiconductor hosts such as zinc sulfide and strontium sulfide which provide hot carriers (greater than two electron volts) which impact excite luminescent centers such as manganese, cerium, and copper.

Sufficient hot carrier generation requires high field strength exceeding a break down field of the phosphor thin film. An alternating current biased dielectric phosphor dielectric layered structure allows reliable high field operation by current limiting of the electrical breakdown of the phosphor layer. Generally these dielectric layers are thin film dielectric layers which are applied by sputtering or the like. As such, the thickness of the dielectric layers is generally limited. The thinness of the dielectric layer limits the voltage which can be applied and further the reliability of the TFEL.

### SUMMARY OF THE INVENTION

The present invention is premised on the realization that a doped wide band gap semiconductor material can be used in forming an alternating current electroluminescent device. More particularly the present invention is premised on the realization that wide band gap semiconductors such as gallium nitride, aluminum nitride or indium nitride doped with an emitting rare earth or other metal can be isolated and subjected to an alternating current to provide electroluminescence. These nitride-based electroluminescent semiconductors have the advantage of high brightness red, green, or blue emission. The nitride-based semiconductors are also extremely rugged which allows them to be electrically driven at high input powers without significant semiconductor degradation. Furthermore, the nitride-based semiconductor is stable up to temperatures as high as 900° C. This high temperature stability allows compatibility of the nitride semiconductor with harsh electroluminescent device fabrication techniques. Fabrication techniques such as screen printing a high performance and high thick film dielectric layer requires a high sintering temperature of >800° C. It is the ruggedness of the nitride semiconductor that allows high temperatures and reactive chemicals to be utilized in device fabrication.

The objects and advantages of the present invention will be further appreciated in the light of the following detailed description and drawings in which:

### BRIEF DESCRIPTION OF THE DRAWINGS

FIG. 1 is a cross-section of an alternating current electroluminescent device of the present invention.

FIG. 2 is a cross-section of a first alternate embodiment of the present invention.

FIG. 3 is a cross-section of a second alternate embodiment of the present invention utilizing thick film deposition techniques.

### DETAILED DESCRIPTION

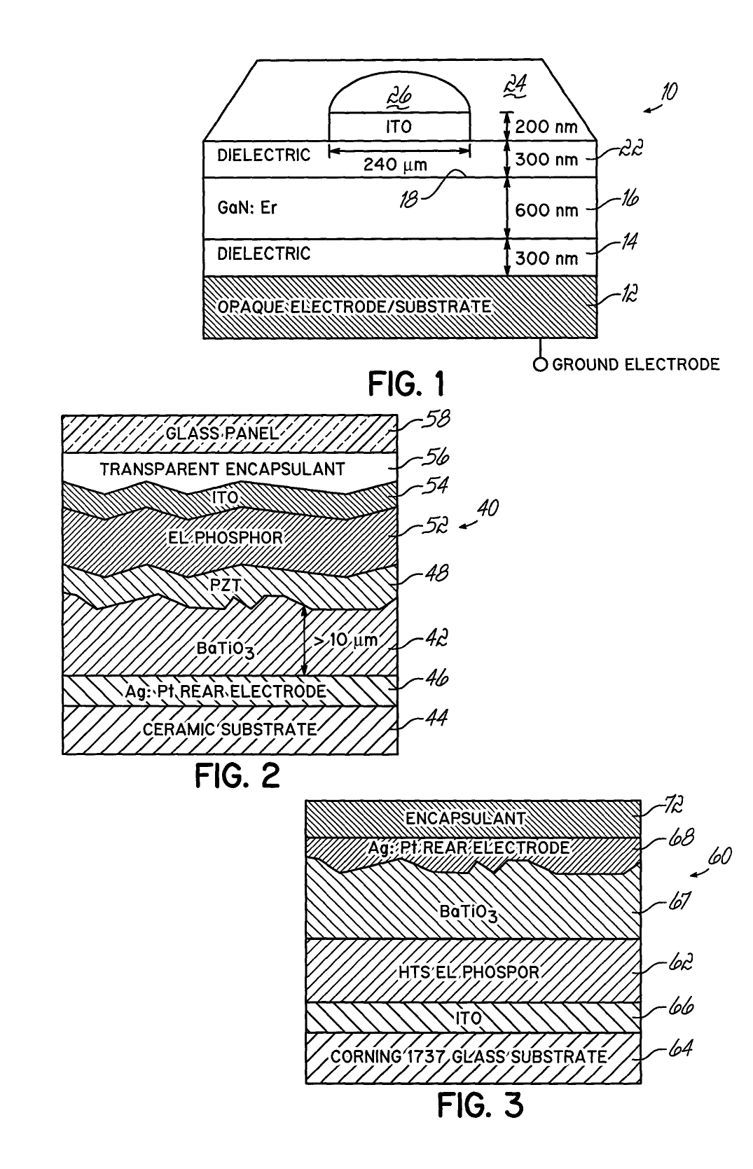

As shown in FIG. 1, the present invention is an electroluminescent device 10 which incorporates a first electrode 12 coated with a thin dielectric layer 14 in turn coated with a phosphor 16 according to the present invention. The upper surface 18 of phosphor 16 is coated with a second dielectric layer 22 which has an outer surface 24 covered in part by a transparent electrode 26 preferably formed from indium tin oxide ITO). The structures shown in the figures are exemplary and show adjacent layers in contact with each other without intervening layers. However, additional layers can be utilized to the extent they do not interfere with the recited layers. Therefore the terms coating and in contact do not exclude the possibility of additional intervening but non-interfering layers.

More particularly the opaque electrode substrate 12 can be generally any conductive material. As shown, this layer 12 is a ground electrode. It will preferably be p⁺ Si. The upper surface 28 is then in turn coated with a thin layer of the dielectric 14. Suitable dielectrics include, but are not limited to, aluminum oxide, aluminum nitride, aluminum titanium oxide, silicon nitride, silicon oxinitride. These can be deposited by a variety of different methods such as radio frequency sputtering and the like.

The thickness of layer 14 should be at least about 200 nm. Increased film thickness permits application of higher applied voltages. However, due to the method of application, the effective thickness is limited. Generally these layers are limited to a thickness of about 200-1000 nm.

The phosphor layer will be a wide band gap semiconductor material doped with a light emitting rare earth element, transition metal or other metal. The preferred wide band gap semiconductors include gallium nitride, aluminum nitride and indium nitride. These can be doped with a variety of elements. Preferred elements for doping include: Pr, Eu, Tb, Er, and Tm.

Any production method which forms poly-crystalline semiconductors can be used to apply the semiconductor phosphor layer. Suitable techniques include molecular beam epitaxy, metalo-organic chemical vapor deposition, chemical vapor deposition, plasma enhanced chemical vapor deposition, hydride vapor phase epitaxy, plasma enhanced chemical deposition, sputtering and evaporation.

The desired thickness of the semiconductor material should be from about 0.02 to 5 microns with 1 to 2 microns being preferred. For the rare earth or metal dopant be strongly optically active in the wide band gap semiconductor, the dopant should substitute for the group III element (Ga, Al or In). This should permit the light emitting element to sit in an optically active site which promotes visible light emission.

Typically the rare earth dopant will be Tm for a blue display, Pr or Eu for a red display and Er or Tb for a green display. These can be added to the semiconductor by either in situ methods or post growth doping using ion implantation or diffusion. Generally the concentration of the dopant is relatively high from less than 0.1% up to about 10 atomic percent or higher. The dopant concentration can be increased until the emission stops. Generally the preferred concentration will be 0.1 to 10 atomic percent.

The method of forming the light emitting semiconductor layer in the present invention is further explained in pending patent application Ser. No. 09/299,186, filed Apr. 23, 1999, entitled Visible Light Emitting Device Formed from Wide BandGap Semiconductor Dopant with a Rare Earth Element is further the subject of published PCT Application US00/10283, both of which are incorporated herein by reference.

As shown in FIG. 1, the semiconductor phosphor layer 16 is then coated with a second dielectric layer 22 generally having the same composition and thickness as the first dielectric layer 14. An electrode preferably a transparent or semitransparent electrode is applied on an outer surface 24 of the second dielectric layer. A suitable electrode is formed from indium tin oxide (ITO).

### EXAMPLE 1

The electroluminescent devices (ELD) for this investigation into GaN:Re ac-TFEL utilize the basic structure shown in FIG. 1. The structure consists of a p⁺-Si substrate and the following layers: 300 nm dielectric/600 nm GaN:Er/300 nm dielectric/200 nm metal (ITO). The dielectrics (Al₂O₃, AlN, Si₃N₄, and SiON) evaluated for GaN:Er ac-ELDs have permittivity similar to that of GaN (˜8). ELDs with an emitting area of ˜1.8×10⁻³ cm² had a corresponding operational capacitance of ˜30 pF. This value is close to what is expected under conditions of electrical breakdown for the GaN:Er layer. The focus in this example is on a ELD structure which uses ˜300 nm of radio frequency sputtered A₂O₃ dielectric layers. The GaN:Er phosphor is deposited by molecular beam epitaxy (MBE) on amorphous insulators. The ac-ELDs were driven with an AVTECH 100 kHz, +/−200 V linear amplifier with 50 kΩ output resistance. The luminance values are measured with a Minolta CS-100 Chroma-Meter and a Newport 1830-C optical power meter.

The GaN:Er films were deposited at ˜700° C. and are polycrystalline with an x-ray diffraction (XRD) linewidth of 0.174° for the (0002) peak.

The GaN:Er ac-ELDs have a strong Er visible emission spectrum. The spectrum is taken from an ELD operated with a ±180 V, 10 kHz square wave. At 180 peak voltage (Vₚ), the peak field applied to Al₂O₃/GaN:Er/Al₂O₃ layers is ˜1.5 MV/cm. The two green emission peaks at ˜537/558 nm are essentially identical to those reported for epitaxially grown GaN:Er dc-ELDs and originate from the relaxation of the ²H_{11/2} and ⁴H_{3/2} excited states to the ⁴I_{15/2} ground state of Er³⁺. The spectrum also contains a strong violet peak at ˜415 nm (²H_{9/2}) and a weaker ultraviolet peak at 389 nm (⁴G_{11/2}). This 415 nm emission corresponds to an energy of ˜3 eV, indicating that the carrier energy distribution is populated to levels exceeding the requirements for a blue TFEL phosphor (˜2.6 eV).

A 170 Vₚ, 1 kHz square wave applied to the GaN:Er ac-ELD results in a luminance of 5 cd/m². An increase in brightness with pulse width is observed and is due to the fact that during most of the pulse duration the electrons are held near the GaN/dielectric interface. When the pulse is off, the electrons which are not trapped at the interface are free to diffuse away. These “wandering” electrons will not be able to achieve full acceleration during the next pulse. By increasing the pulse width, we increase the number of electrons which can reach the necessary energy for impact excitation of the Er ions. The effect of charge trapping can be readily observed by comparing bipolar and monopolar biasing of the device at the same duty ratio. Strong charge trapping leads to a much brighter emission under bipolar biasing. An increase of 2× for bipolar versus monopolar operation is observed. This indicates that only a moderate amount of trapping is present.

The frequency dependence of the visible (537/558 nm) and infrared (IR) emission (1550 nm) was studied for 170 Vₚ square wave excitation. At 100 kHz a brightness of 300 cd/m² was obtained for the visible emission. The infrared (1550 nm) GaN:Er emission originates from relaxation of the lowest excited Er³⁺ state (⁴I_{13/2}) and is on interest for optical communications. At low frequency (<1 kHz) the expected linear relation between frequency and visible and IR emission intensity is observed, with roughly as many photons emitted in the IR as in the green. As the frequency increases beyond 1 kHz there is a clear saturation of the IR intensity. The visible emission intensity also increases sublinearly with frequency at higher frequencies. One can use the frequency for which a 3 dB reduction from the linear relation occurs as an indicator of the onset of this saturation process. We obtain 3 dB frequencies of ˜65 and ˜8 kHz for the visible and IR emission intensities, respectively. The frequency saturation process can be related to the GaN:Er excited state lifetime of each particular transition, which have been measured to be on the order of ˜10 microns for the visible green emission and ˜1 ms for the 1.5 μm IR emission. At low frequency (<1 kHz) an Er atom will have adequate time to radiatively (˜537/558 nm) relax from higher excited states to the ground state or to nonradiatively relax to the IR level and then radiatively relax to the ground state. According to this argument the emission intensity will saturate as the frequency exceeds the inverse of the corresponding excited state lifetime. Based on the lifetime argument, saturation in the IR signal should be noticeable at ˜1 and at ˜100 kHz for the visible signal. The agreement with the 3 dB frequency is fairly good in the case of the visible signal, but not for the IR signal where saturation at a lower frequency is predicted.

FIGS. 2 and 3 show alternate embodiments of the present invention utilizing thick dielectric films. Thick dielectric films are generally greater than ten microns and in particular are applied by physical coating methods as opposed to chemical (i.e., gas phase or plasma phase) coating methods. The dielectric layer is applied as a gel. The preferred method of applying the dielectric is simply screen printing.

As shown in FIG. 2, an electroluminescent device 40 with a thick dielectric layer 42 is formed by initially coating a ceramic substrate 44 with a solid electrode such as silver platinum electrode 46. This is then screen coated with more than ten microns of a dielectric such as bariun titanate 42 which is then heated to a temperature above 850° C. to densify the barium titanate and cause crystallization. This layer is then coated with a layer 48 of lead zinc titanate which acts to in effect smooth the surface. The electroluminescent phosphor 52 is then applied over layer 48 in the manner previously described using preferably gallium nitride doped with erbium, thulium or praseodymium. Layer 52 is coated with a clear indium tin oxide electrode 54 and subsequently preferably a transparent encapsulant 56 followed by a glass panel 58 which is simply adhered to the structure by the transparent encapsulant. Suitable encapsulants include Dupont 8185 and Honeywell Aclar brand film. This structure will provide electroluminescence emitted through the glass panel 58 when alternating a current is applied between the ITO electrode and the silver platinum electrode.

FIG. 3 shows a preferred electroluminescent device 60 of the present invention in which the electroluminescent phosphor 62 is applied using a method which allows it to emit almost directly through a glass substrate 64. In this embodiment, the initial substrate 64 is simply a glass substrate such as Corning 1737 glass substrate. Other high temperature glasses typically used in electroluminescent devices can be utilized.

Substrate 64 is coated with the indium tin oxide electrode 66 followed by a high temperature stable electroluminescent phosphor. Preferably for use in the present invention, it will be rare earth doped gallium nitride, indium nitride or aluminum nitride.

The high temperature stable electroluminescent phosphor has a thick coating of dielectric, again greater than 10 microns preferably applied by screen printing. Dielectric layer 67 once applied is then heated up briefly to densify the dielectric, preferably at a temperature below the strain temperature of the glass substrate. Barium titanium oxide is preferably heated to about 600° C. for ten minutes. This is followed by a very brief high temperature treatment at 800-850° C. for one to ten minutes effective to cause densification and/or crystallization of the dielectric. The dielectric layer 67 is coated with an electrode 68 that can be transparent or nontransparent followed by a hermetic encapsulant 72.

When alternating current is applied between the electrode 66 indium tin oxide and the rear electrode 68, light will be emitted from the layer 62 phosphor through the indium tin oxide 66 and through the glass 64. This structure has the advantage that the phosphor is applied to a relatively smooth surface as opposed to the much rougher surface with the embodiment shown in FIG. 2. It further reduces processing steps requiring only one dielectric. Further, the dielectric has significantly greater effectiveness than can be practically achieved using two thick layer dielectrics. This will be appreciated and further in light of the following detailed discussion.

### EXAMPLE 2

To form a green light emitting TDEL structure, transparent indium tin oxide (ITO) thin film layer was sputtered onto a Corning 1737 glass substrate and annealed at 400° C. for 60 s in order to form the front electrode. The glass substrate which is widely used in Active-Matrix LCD manufacturing was not warped or distorted since it has a thermal strain point of 666° C. A green thin film (˜1 micron) EL phosphor layer (GaN:Er) was then deposited in a single pump-down between diffusion barrier layers of AlN by evaporation of solid Ga, Er and Al sources in the presence of a nitrogen plasma. During phosphor layer deposition the substrate was held at temperatures (<600° C.) below the thermal strain point of the glass substrate. A thick film dielectric layer was then screen printed using Dupont 5540 BTO paste, prefired at 600° C. for 20 minutes and then fired at 825° C. for four minutes resulting in a BTO layer thickness of ˜20 micron. Even though this is below the preferred firing sequence for the BTO (10 minutes at 850° C.), the resulting permittivity of the dielectric firing layer was 1000. (If two BTO layers were to be screen printed, the first BTO layer would be prefired before the second BTO layer was screen printed.) The glass substrate was not warped or distorted since it was held above its thermal strain point for a very brief time. To complete the TDEL structure rear Pt electrodes were sputtered through a stencil mask, the resulting Pt dots defining the emitting area of the EL devices.

The rear electrodes could be deposited by screen printing of Dupont 9970 Ag:Pt past with individual device dimensions down to 100 micron. The Ag:Pt rear electrodes would be screen printed onto a prefired BTO layer and then the whole TDEL structure can be fired at 825° C. for four minutes. In fabricating a high resolution FPD, this method of forming the rear electrodes is preferred since rear electrode misalignment caused by slight warpage/shrinkage of the glass substrate during the 825° C. firing cycle is avoided.

The resulting TDEL structure was biased with a 1 kHz wave and exhibited a luminance of 10 cd/m² when biased at 170Vp. These preliminary TDEL devices were tested unsealed in a 40% humidity environment and demonstrated a promising 50% brightness operating lifetime of ˜1000 hours. The emission from the TDEL devices is very uniform even at sub-pixel dimensions (<0.5 mm). Depositing the phosphor layer first onto the smooth surface of the ITO-coated glass substrate and then forming the thick film dielectric layer results in an emission uniformity similar to that of an all-thin film EL structure as shown in FIG. 1. The TDEL structure may be implemented without an additional layer between the phosphor and thick film dielectric layer. With the dielectric layer and firing temperatures used in this example, only a high temperature and chemically stable semiconductor such as gallium nitride can be used for the light emitting layer.

The present invention can then be used to form a flat screen display device by simply forming red, green and blue electroluminescent devices adjacent to each other. Basically thousands of the electroluminescent devices would be formed over an area preferably utilizing the embodiment shown in FIG. 3. This would then enable a flat screen display device such as a television, computer monitor or the like. Due to the structure, it would form an intense display which is not currently available utilizing electroluminescence. Further, the cost of manufacturing is significantly reduced due to the ability to screen print the dielectric onto the structure. Further utilizing the thick dielectric film significantly enhances the reliability of the electroluminescent device of the present invention.

This has been a description of the present invention along with a preferred method of practicing the invention.

However, the invention itself should be defined only by the appended claim, wherein we claim:

1. An alternating current electroluminescent device comprising a visible light emitting semiconductor comprising a wide band gap semiconductor doped with a light emitting element wherein said semiconductor is selected from the group consisting of indium nitride, gallium nitride and aluminum nitride;
wherein said first surface of said semiconductor is coated with a dielectric;
said semiconductor having a first and second surface; and
a source of alternating current applied through said dielectric and said semiconductor.

2. The electroluminescent device claimed in claim 1 further comprising a second dielectric layer coating a second surface of said semiconductor.

3. The electroluminescent device claimed in claim 2 wherein said dielectric layers are selected from the group consisting of silicon nitride, aluminum nitride, aluminum tin oxide and aluminum oxide and silicon oxinitride.

4. The electroluminescent device claimed in claim 1 wherein said source of alternating current comprises a first electrode applied to a first side of said semiconductor and a second electrode applied to a second side of said semiconductor.

5. The electroluminescent device claimed in claim 4 wherein at least one of said electrodes is transparent.

6. A plurality of adjacent electroluminescent devices having the structure claimed in claim 1 wherein adjacent devices have electroluminescent semiconductor layers doped with different dopants whereby said adjacent electroluminescent devices emit different colors.
